(19) United States
(12) Patent Application Publication
(10) Pub. No.: US 2005/0081905 A1
(43) Pub. Date: Apr. 21, 2005

(54) Thermopile IR detector package structure

(76) Inventors: Alex H. Lan, Hsinchu (TW); Ping-Kuo Weng, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/686,612

(22) Filed: Oct. 17, 2003

(51) Int. Cl. H01L 35/28

(52) U.S. Cl. 136/224

(57) ABSTRACT

A thermopile IR detector package structure makes use of the silicon micro-electro-mechanical processing technique fabricate an encapsulation having a cavity. The encapsulation is then installed onto a substrate of a detector to seal thermoelectric components on the substrate. In addition to having the sealing function, the encapsulation also has the function of detecting the spectrum and field of view. Next, a carrier substrate is combined with sensing components to form a surface mount device applicable to assembly and fabrication of various related circuits. The thermopile IR detector package structure not only facilitates mass production and reduces fabrication process, material, volume ad weight, but the formed surface mount device is also in agreement with automatically produced electronic components.

### FIELD OF THE INVENTION

The present invention relates to a thermopile IR detector package structure and, more particularly, to a technique making use of the silicon micro-electro-mechanical processing technique to fabricate devices and encapsulations. This kind of package structure can fabricate thermopile IR detection surface mount devices to match automatic production trend of the surface mount technology (SMT).

### BACKGROUND OF THE INVENTION

Using a thermocouple for temperature measurement is a well-known technique. When two different kinds of metals (conductors) make up a loop, a voltage will be generated if the temperatures of two joints are different. This thermoelectric characteristic is called the Seebeck effect. The temperature difference of two ends of a thermocouple can be known by measuring the magnitude of the Seebeck voltage.

Through a special structure design, a thermocouple can be used for thermal radiation measurement by the temperature difference of two joints caused by absorption of thermal radiation. Early thermocouple is usually made of metal filaments (e.g., Cu-Constantan). It is found later semiconductor materials have higher thermoelectric constants. Therefore, semiconductor thermocouples have been developed for weak thermal radiation measurement. However, the thermoelectric voltage provided by a single thermocouple is much limited. Several tens or hundreds of thermocouples are thus series-connected to form a so-called thermopile for enhancing the thermoelectric voltage signal. This thermoelectric voltage is proportional to the number of thermocouples, the thermoelectric constant of material, the temperature difference of cold and hot joints and so on.

In recent years, along with popularity of the silicon micro-electro-mechanical processing technique, high-performance thermopile structures with low thermal capacities and high thermal insulating characteristics have been disclosed. These structures makes use of semiconductor fabrication materials (e.g., poly-silicon and aluminum) as thermocouples and the semiconductor mass production technique for providing thermopiles of high quality and low cost. Thermopile IR detectors mainly apply to temperature measurement and monitoring such as ear thermometers, hair dryers, microwave ovens and the car industry and gas detection based on IR absorption characteristics.

Conventional thermopile IR detectors are mainly packaged with the standard TO-5 or TO-18 metal transistor package, as shown in FIG. 1. In this package structure, the front end of a front metal encapsulation is perforated, and an IR-transparent material is then filled in. An anti-reflection film is usually coated on this IR-transparent material to enhance the transmittance of IR rays and define an appropriate transparent wave band. However, this kind of metal transistor package has a complicated fabrication process, a large size and a high cost. Moreover, during the fabrication of printed circuits, the fabrication process is incompatible with the existent surface mount technique. Because extra processing procedures are required, the production cost like the size and material of required circuit board, the manpower and time will increase.

Accordingly, the present invention proposes a thermopile IR detector package structure to solve the problems in the prior art.

### SUMMARY AND OBJECTS OF THE PRESENT INVENTION

The primary object of the present invention is to provide a thermopile IR detector package structure, which makes use of an encapsulation formed by the silicon micro-electro-mechanical technique to seal a detector. In addition to having the sealing function, this encapsulation has also the function of detecting the spectrum and the field of view.

Another object of the present invention is to provide a thermopile IR detector package structure, which can match a substrate to form a surface mount device (SMD) for facilitating mass production and reducing the fabrication procedures, material, volume and weight.

Yet another object of the present invention is to provide a thermopile IR detector package structure, which can form a thermopile IR detector SMD to be in agreement with existent automatically produced electronic components. Manufacturers can thus adopt automatic production equipments to reduce the production procedures and time and lower the cost of system manufacturing, hence facilitating mass production and effectively solving the problems in the prior art.

To achieve the above objects, the present invention proposes a new thermopile IR detector package structure, which comprises a detector and an encapsulation. Thermoelectric components are formed on a substrate of the detector. The encapsulation is installed above the substrate of the detector to seal the thermoelectric components thereon. This encapsulation is formed by etching a cavity in a silicon substrate.

Moreover, the present invention further coating an anti-reflection multi-layer film on the inner and outer surfaces of the encapsulation. A metal shield layer is then coated on the outer surface of the encapsulation. The field of view (FOV) of the detector is controlled through the thickness of the encapsulation and the metal shield layer. Besides, the FOV of the detector can also be controlled through the size and etched depth of the encapsulation.

The various objects and advantages of the present invention will be more readily understood from the following detailed description when read in conjunction with the appended drawings, in which:

### BRIEF DESCRIPTION OF DRAWINGS

FIG. 1 is a structure diagram of a conventional thermopile IR detector adopting the standard TO-5 or TO-18 metal transistor package;

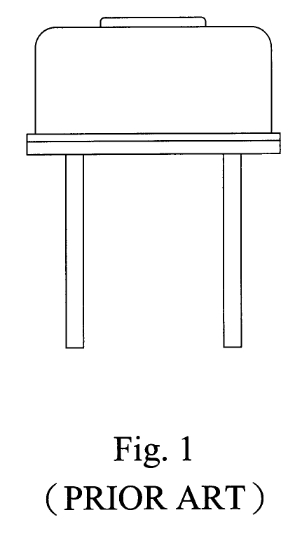

FIG. 2 is a package structure diagram of the present invention;

FIG. 3 shows a package structure having a metal shield layer of the present invention;

FIG. 4 is a structure diagram of the present invention packaged into a leadless chip carrier (LCC) type;

FIG. 5 is a structure diagram of the present invention packaged into a small outline integrated circuit (SOIC) type;

FIG. 6 is a structure diagram of the present invention packaged into a ball grid array (BGA) type; and

FIG. 7 is a structure diagram of the present invention packaged into a chip on board (COB) type.

### DETAILED DESCRIPTION OF PREFERRED EMBODIMENT

The present invention provides a new thermopile IR detector package structure, which makes use of an encapsulation formed by the silicon micro-electro-mechanical technique to seal a detector, and a carrier substrate is matched to form an SMD for facilitating mass production and reducing the fabrication procedures, material, volume and weight. The conventional TO-5 or TO-18 package can thus be replaced.

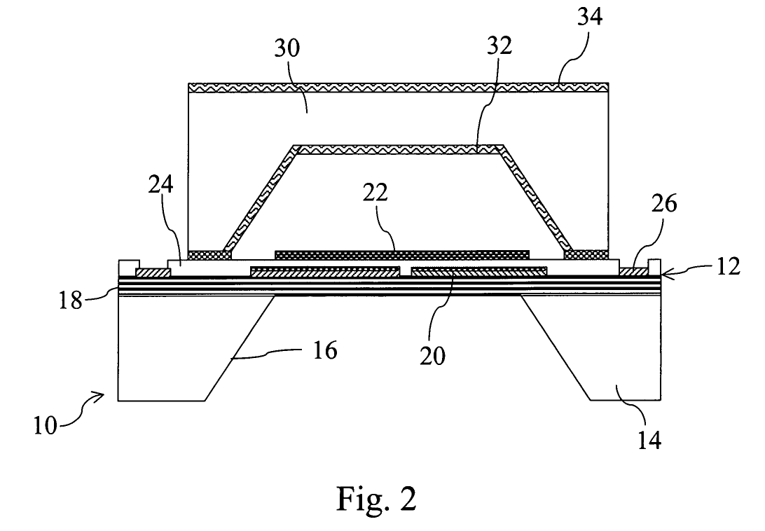

As shown in FIG. 2, the package structure of a thermopile IR detector 10 comprises a thermopile detector 12 and an encapsulation 30. The detector 12 includes a single-silicon substrate 14. A cavity portion 16 is etched in the substrate 14 through chemical etching. A thin-film float board 18 covers over the cavity portion 16. The thin-film float board 18 is composed of more than one layer of insulating films, preferred to be silicon oxide and silicon nitride. One or a plurality of thermoelectric components 20 are then arranged on the thin-film float board 18. These thermoelectric components 20 are used to form a hot joint and a cold joint. The hot joint is arranged at the center of the thin-film float board 18, while the cold joint is arranged beside the substrate 14. After the thin-film float board 18 is illuminated by light, the temperature is distributed with the center has the highest value and then diminishes toward the surrounding. A blackbody radiation absorbing layer 22 for IR absorption is arranged at the uppermost layer of the thermoelectric components 20 through the help of an insulating layer of silicon oxide or silicon nitride. It is necessary for this blackbody radiation absorbing layer 22 to cover the hot joint but not cover the cold joint. A plurality of metal pads 26 are provided on the substrate 14 around the thermoelectric components 20 to be used as contact pads in the subsequent wire-bonding procedure.

Next, a mold 28 is used to install the encapsulation 30 formed by etching a cavity in a silicon substrate on the surface of the insulating layer 24 on the substrate 14 of the detector 12 for sealing the thermoelectric components 20 thereon. Anti-reflecting multi-layer films 32 and 34 are coated on the inner and outer surfaces of the encapsulation 30, respectively.

The cavity is etched in the silicon substrate by using silicon anisotropic etching technique or silicon isotropic etching technique. Although the shapes of the formed encapsulations are different, their functions are the same. In addition to using the mold 28 for sealing the encapsulation 30 and the detector 12, solder or low-temperature glass can also be used.

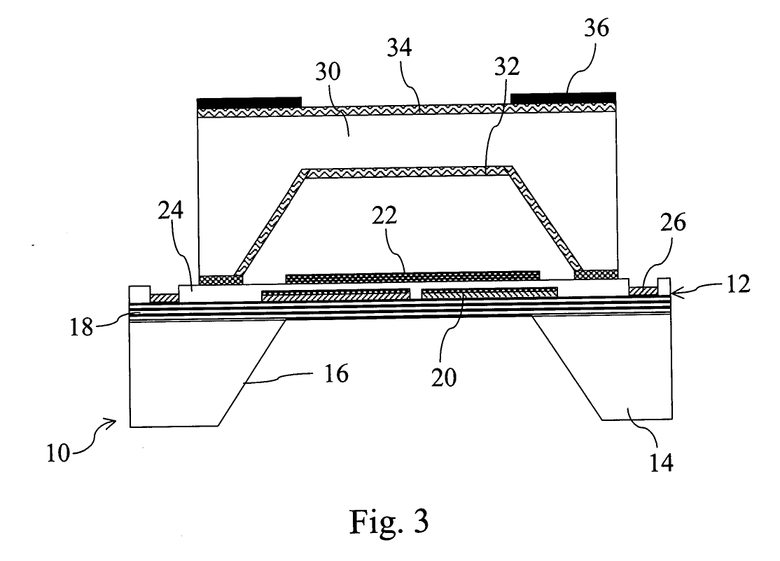

In the present invention, a silicon substrate of an appropriate thickness is used to make the encapsulation 30. IR rays incident to the inner bevel edges of the encapsulation 30 won't be absorbed by the detector 12 due to total reflection. Therefore, the viewing angle of the detector 10 is mainly determined by the size of the thin board region of the encapsulation 30 and the distance from the thin board to the detector 12. The distance from the thin board to the detector 12 is mainly controlled by the etched depth. Moreover, in order to have a better effect of the viewing angle, a metal shield layer 36 can be coated on the surface of the anti-reflection multi-layer film 34 on the outer surface of the encapsulation 30, as shown in FIG. 3. The FOV of the detector 10 can thus be defined by the thickness of the encapsulation 30 and the metal shield layer 36.

Besides, along with the trend of compactness of electric products, components used in existent circuit boards are mainly packaged with SMD regardless of active or passive components to facilitate quick automatic production and mass production. The thermopile IR detectors disclosed in the present invention can be easily packaged into various types of SMD to conform to the present technique trend.

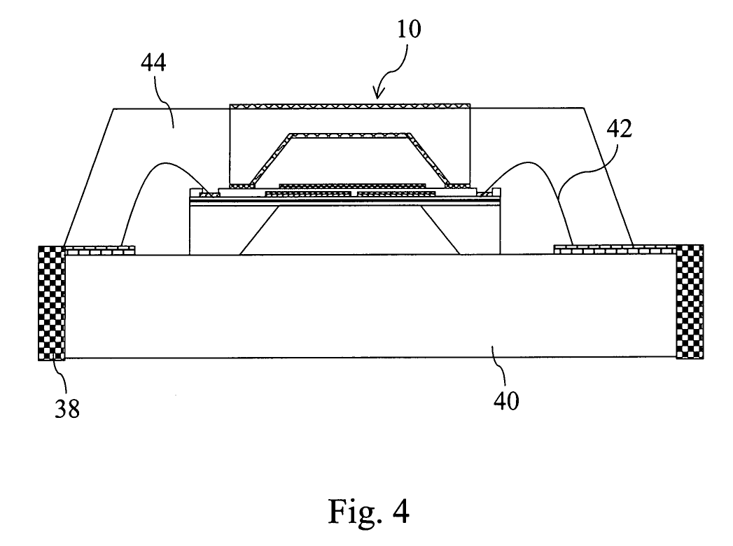

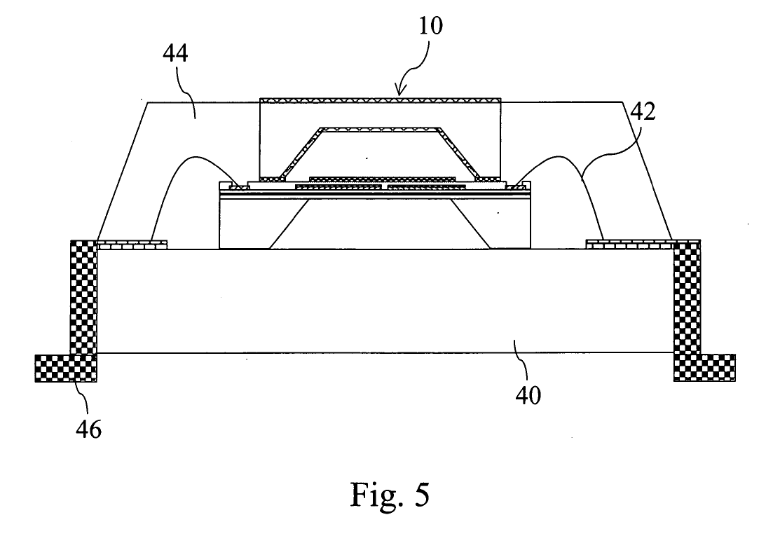

As shown in FIG. 4, the thermopile IR detector 10 is installed and fixed on a carrier substrate 40 already having wiring and solders 38 thereon. The carrier substrate 40 is usually an alumina substrate or a printed circuit board. The solders 38 are used as outward conducting contacts. A plurality of bonding wires 42 are used to connect signal lines onto the carrier substrate 40. Finally, a mold 44 is coated to protect the bonding wires 42 and enhance the mechanical strength. A leadless chip carrier (LCC) type SMD is thus formed. If the solders 38 on the carrier substrate 40 are replaced with a plurality of solder pins 46, a small outline integrated circuit (SOIC) type SMD will be formed, as shown in FIG. 5.

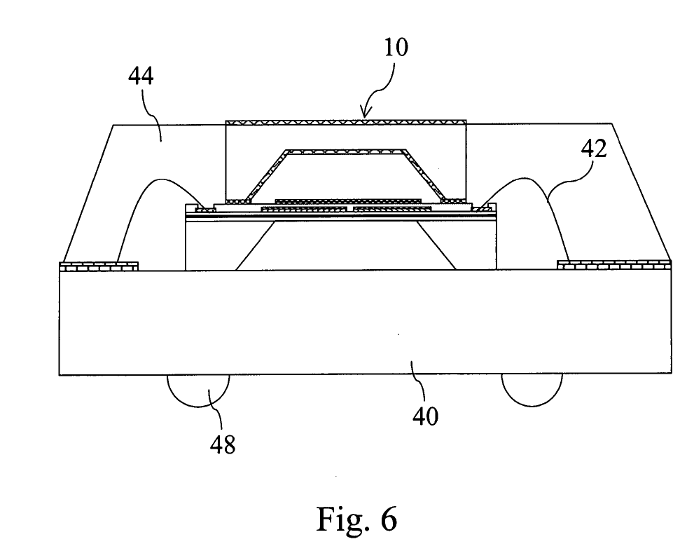

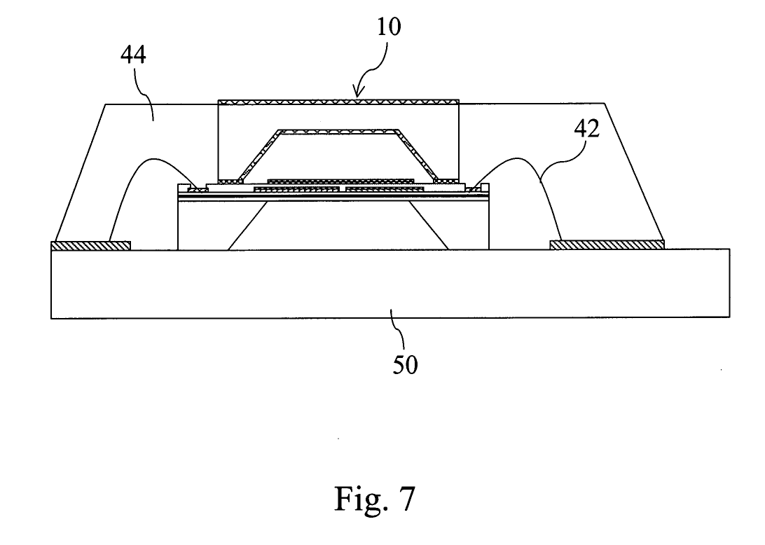

A ball grid array (BGA) type SMD can also be formed in the present invention. As shown in FIG. 6, a plurality of solder balls 48 are provided on the bottom face of the carrier substrate 40. These solder balls 48 are used as outward conducting contacts of the detector 10. Besides, the detector 10 can further be directly packaged onto a circuit board 50. As shown in FIG. 7, the detector 10 is electrically connected to the circuit board 50 by using bonding wires 42 to form a chip on board (COB) type circuit board.

A thermo-sensitive resistor or diode can further be arranged on the above carrier substrate for temperature measurement of the main body.

To sum up, the present invention makes use of an encapsulation formed by the silicon micro-electro-mechanical processing technique to seal a detector. Next, anti-reflection multi-layer films are respectively coated on the inner and outer surfaces of the encapsulation to enhance the transmittance and limit the spectrum of the detector. The size of a thin board of the encapsulation, the etched depth of a cavity, and the size of a metal shield layer are properly designed to control the field of view of the detector. A carrier substrate is simultaneously matched to form a thermopile IR detector SMD. Through the thermopile IR detector package structure of the present invention, the fabrication procedures, material, volume and weight can be reduced. Moreover, manufacturers can adopt automatic production equipments to decrease the production procedures and time and lower the cost of system manufacturing, hence facilitating mass production and effectively solving the problems in the prior art.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

1. A thermopile IR detector package structure comprising:
a detector having a substrate with thermoelectric components formed thereon; and
an encapsulation formed by etching a cavity in a silicon substrate, said encapsulation being installed on said substrate of said detector to seal said thermoelectric components thereon.

2. The thermopile IR detector package structure as claimed in claim 1, wherein said detector comprises:
said substrate having a cavity portion;
a thin-film float board located above said cavity portion;
a plurality of thermoelectric components formed on said thin-film float board;
an insulating layer located above said thermoelectric components; and
a blackbody radiation absorbing layer covering on said insulating layer.

3. The thermopile IR detector package structure as claimed in claim 2, wherein said thin-film float board is an insulating structure composed of more than one layer of thin film, and is preferably made of silicon oxide and silicon nitride.

4. The thermopile IR detector package structure as claimed in claim 1, wherein an antireflection multi-layer film is further provided on inner and outer surfaces of said encapsulation.

5. The thermopile IR detector package structure as claimed in claim 1, wherein a metal shield layer is coated on the outer surface of said encapsulation.

6. The thermopile IR detector package structure as claimed in claim 5, wherein the size of said metal shield layer can be exploited to control the field of view of said detector.

7. The thermopile IR detector package structure as claimed in claim 1, wherein the size and etch depth of said encapsulation can be exploited to control the field of view of said detector.

8. The thermopile IR detector package structure as claimed in claim 1, wherein a pit is etched in said silicon substrate by means of silicon anisotropic etching technique.

9. The thermopile IR detector package structure as claimed in claim 1, wherein a pit is etched in said silicon substrate by means of silicon isotropic etching technique.

10. The thermopile IR detector package structure as claimed in claim 1, wherein said encapsulation makes use of mold, solder or low-temperature glass to seal said detector.

11. The thermopile IR detector package structure as claimed in claim 1, wherein a carrier substrate is further provided below said substrate of said detector, and a plurality of external conducting contacts are formed thereon to form a surface mount device.

12. The thermopile IR detector package structure as claimed in claim 11, wherein said carrier substrate is an alumina substrate or a printed circuit board.

13. The thermopile IR detector package structure as claimed in claim 11 or 12, wherein a thermo-sensitive resistor or a diode can further be provided on said carrier substrate for temperature measurement of the main body.

14. The thermopile IR detector package structure as claimed in claim 11, wherein said external conducting contacts are solders, solder pins or solder balls.

15. The thermopile IR detector package structure as claimed in claim 1, wherein said detector can be directly packaged onto a circuit board.
